(19) United States
(12) Patent Application Publication
(10) Pub. No.: US 2022/0243336 A1
(43) Pub. Date: Aug. 4, 2022

(54) STORAGE CONTAINER AND PROCESSING SYSTEM

(71) Applicant: Tokyo Electron Limited, Tokyo (JP)

(72) Inventors: Norihiko AMIKURA, Miyagi (JP); Masatomo KITA, Miyagi (JP); Toshiyuki MAKABE, Miyagi (JP)

(73) Assignee: Tokyo Electron Limited, Tokyo (JP)

(21) Appl. No.: 17/589,907

(22) Filed: Feb. 1, 2022

(30) Foreign Application Priority Data
Feb. 1, 2021 (JP) 2021-014289

(51) Int. Cl. C23C 16/54; C23C 16/505; C23C 16/458

(52) U.S. Cl. CPC C23C 16/54; C23C 16/4585; C23C 16/505

(57) ABSTRACT

A storage container for accommodating an annular member having a notch on at least one of an outer circumference and an inner circumference thereof is disclosed. The storage container comprises a base plate on which the annular member is placed. The base plate comprises a plurality of guide pins that protrude from the base plate and are configured to position the annular member. The plurality of guide pins include a pin engaged with the notch.

### CROSS-REFERENCE TO RELATED APPLICATION

This application claims priority to Japanese Patent Application No. 2021-014289 filed on Feb. 1, 2021, the entire contents of which are incorporated herein by reference.

### TECHNICAL FIELD

The present disclosure relates to a storage container and a processing system.

### BACKGROUND

There is known a technique using a single lifter pin for raising and lowering an edge ring and a cover ring arranged around a wafer on an electrostatic chuck disposed in a processing chamber where plasma processing is performed and transferring one member at a time (see, e.g., Japanese Laid-open Patent Publication No. 2020-113603).

### SUMMARY

The present disclosure provides a technique for positioning and accommodating a consumable part.

In accordance with an aspect of the present disclosure, there is provided a storage container for accommodating an annular member having a notch on at least one of an outer circumference and an inner circumference thereof, comprising: a base plate on which the annular member is placed. The base plate comprises a plurality of guide pins that protrude from the base plate and are configured to position the annular member, and the plurality of guide pins include a pin engaged with the notch.

### BRIEF DESCRIPTION OF THE DRAWINGS

FIG. 1 shows an example of a processing system according to an embodiment.

FIG. 2 is a schematic cross-sectional view showing an example of a process module.

FIG. 3 is a front cross-sectional view showing an example of a storage module.

FIG. 4 is a side cross-sectional view showing the example of the storage module.

FIG. 5 is a schematic plan view showing an upper fork that is not holding an object to be transferred.

FIG. 6 is a schematic plan view showing the upper fork holding a first assembly.

FIG. 7 is a schematic plan view showing the upper fork holding a second assembly.

FIG. 8 is a schematic plan view showing the upper fork holding only a transfer jig.

FIG. 9 is a schematic perspective view showing an example of a cassette in the storage module.

FIGS. 10A to 10C show an example of a positioning mechanism for an edge ring.

FIGS. 11A to 11C show an example of a positioning mechanism for a cover ring.

FIGS. 12A to 12C show an example of a positioning mechanism for an edge ring and a cover ring.

FIG. 13 shows another example of the positioning mechanism for an edge ring and a cover ring.

FIG. 14 is a schematic plan view showing an example of the second assembly accommodated in the cassette.

FIG. 15 is a schematic plan view showing an example of the transfer jig accommodated in the cassette.

FIG. 16 is a schematic perspective view showing another example of the cassette in the storage module.

FIGS. 17A and 17B schematically show an electrostatic chuck on which the edge ring and the cover ring are placed.

FIGS. 18A to 18D show an example of a simultaneous transfer mode.

FIGS. 19A and 19B schematically show an electrostatic chuck on which the edge ring and the cover ring are placed.

FIGS. 20A to 20D are first diagrams showing an example of a single transfer mode.

FIGS. 21A to 21D are second diagrams showing the example of the single transfer mode, in which FIG. 21A illustrates the transfer of an upper fork with elevated pins, FIG. 21B illustrates a lowering of the pins, FIG. 2C illustrates a retraction of the upper fork, and FIG. 2D illustrates a lowering of the support pins.

FIG. 22 is a flowchart showing an example of a method of replacing a consumable part according to an embodiment.

FIG. 23 is a schematic cross-sectional view showing another example of the process module.

FIG. 24 shows a state of an elevating mechanism in the simultaneous transfer mode.

FIG. 25 shows a state of the elevating mechanism in the single transfer mode.

### DETAILED DESCRIPTION

Hereinafter, non-limiting exemplary embodiments of the present disclosure will be described with reference to the accompanying drawings. Like or corresponding reference numerals will be given to like or corresponding parts or components throughout the accompanying drawings, and redundant description thereof will be omitted.

(Processing System)

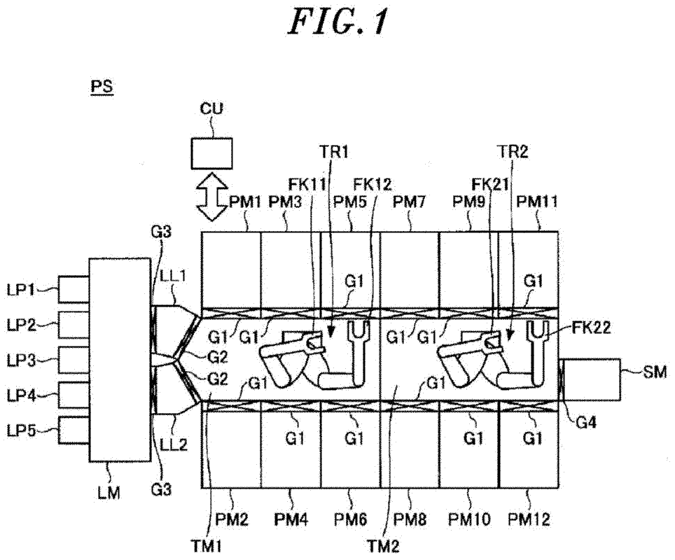

An example of a processing system according to an embodiment will be described with reference to FIG. 1. As shown in FIG. 1, a processing system PS can perform various processes such as plasma processing and the like on a substrate. The substrate may be, e.g., a semiconductor wafer.

The processing system PS includes vacuum transfer modules TM1 and TM2, process modules PM1 and PM12, load-lock modules LL1 and LL2, an atmospheric transfer module LM, a storage module SM, and the like.

Each of the vacuum transfer modules TM1 and TM2 has a substantially quadrilateral shape in plan view. The process modules PM1 to PM6 are connected to two opposite side surfaces of the vacuum transfer module TM1. The load-lock modules LL1 and LL2 are connected to one of the remaining two opposite side surfaces of the vacuum transfer module TM1, and a path (not shown) to be connected to the vacuum transfer module TM2 is connected to the other side surface thereof. The side surfaces of the vacuum transfer module TM1 to which the load-lock modules LL1 and LL2 are connected are angled by the two load-lock modules LL1 and LL2. The process modules PM7 to PM12 are connected to two opposite side surfaces of the vacuum transfer module TM2. A path (not shown) to be connected to the vacuum transfer module TM1 is connected to one of the remaining two opposite side surfaces of the vacuum transfer module TM2, and a storage module SM is connected to the other side surface thereof. The vacuum transfer modules TM1 and TM2 comprise vacuum chambers, and transfer robots TR1 and TR2 are disposed therein, respectively.

The transfer robots TR1 and TR2 are configured to be rotatable, extensible/contractible, and vertically movable. The transfer robot TR1 holds and transfers a substrate and a consumable part using an upper fork FK11 and a lower fork FK12 disposed at a tip end thereof. In the example of FIG. 1, the transfer robot TR1 holds the substrate and the consumable part using the upper fork FK11 and the lower fork FK12 and transfers them between the load-lock modules LL1 and LL2, the process modules PM1 to PM6, and the path (not shown). The transfer robot TR2 holds and transfers the substrate and the consumable part using an upper fork FK21 and a lower fork FK22 disposed at a tip end thereof. In the example of FIG. 1, the transfer robot TR2 holds the substrate and the consumable part using the upper fork FK21 and the lower fork FK22 and transfers them between the process modules PM7 to PM12, the storage module SM, and the path (not shown). The consumable part is replaceably attached to the process modules PM1 to PM12, and consumed by performing various processes such as plasma processing and the like in the process modules PM1 to PM12. The consumable part includes, e.g., an edge ring FR, a cover ring CR, and a ceiling plate 121 of the upper electrode 12, which will be described later.

The process modules PM1 to PM12 comprise processing chambers, and stages (placement tables) disposed therein. After the substrates are placed on the stages, the process modules PM1 to PM12 are depressurized to introduce a processing gas. Then, an RF power is applied to generate plasma, and the substrate is subjected to plasma processing using the plasma. The vacuum transfer modules TM1 and TM2 and the process modules PM1 to PM12 are separated by gate valves G1 that can be opened and closed. The edge ring FR, the cover ring CR, or the like is disposed on the stage. An upper electrode 12 for applying an RF power is disposed above the stage to face the stage.

The load-lock modules LL1 and LL2 are disposed between the vacuum transfer module TM1 and the atmospheric transfer module LM. The load-lock modules LL1 and LL2 comprise variable pressure chambers the internal pressure of which can be switched between a vacuum state and an atmospheric pressure. The load-lock modules LL1 and LL2 comprise stages disposed therein. In the case of loading the substrates from the atmospheric transfer module LM to the vacuum transfer module TM1, the load-lock modules LL1 and LL2 receive the substrates from the atmospheric transfer module LM while maintaining the inside at an atmospheric pressure, and decrease the internal pressure to load the substrates into the vacuum transfer module TM1. In the case of unloading the substrates from the vacuum transfer module TM1 to the atmosphere transfer module LM, the load-lock modules LL1 and LL2 receive the substrates from the vacuum transfer module TM1 while maintain the inside in a vacuum state, and increase the internal pressure up to the atmospheric pressure to load the substrates into the atmospheric transfer module LM. The load-lock modules LL1 and LL2 and the vacuum transfer module TM1 are separated by a gate valve G2 that can be opened and closed. The load-lock modules LL1 and LL2 and the atmospheric transfer module LM are separated by a gate valve G3 that can be opened and closed.

The atmospheric transfer module LM is disposed to be opposite to the vacuum transfer module TM1. The atmospheric transfer module LM may be, e.g., an equipment front end module (EFEM). The atmospheric transfer module LM is an atmospheric transfer chamber that has a rectangular parallelepiped shape, includes a fan filter unit (FFU) and is maintained at an atmospheric pressure. The two load-lock modules LL1 and LL2 are connected to one long side along the longitudinal direction of the atmospheric transfer module LM. Load ports LP1 to LP5 are connected to the other long side along the longitudinal direction of the atmospheric transfer module LM. A container (not shown) accommodating a plurality of (e.g., 25) substrates is placed on each of the load ports LP1 to LP5. The container may be, e.g., a front opening unified pod (FOUP). A transfer robot (not shown) is disposed in the atmospheric transfer module LM. The transfer robot transfers a substrate between the FOUP and the variable pressure chambers of the load-lock modules LL1 and LL2.

The storage module SM is detachably connected to the vacuum transfer module TM2. The storage module SM comprises a storage chamber and stores a consumable part. The storage module SM is connected to the vacuum transfer module TM2 when the consumable parts in the process modules PM1 to PM12 are replaced, and is removed from the vacuum transfer module TM2 after the replacement of the consumable parts is completed. Accordingly, it is possible to effectively utilize the area around the processing system PS. However, the storage module SM may be constantly connected to the vacuum transfer module TM2. The storage module SM comprises a position detection sensor for detecting a position of the consumable part stored in the storage chamber. The consumable parts are transferred between the process modules PM1 and PM12 and the storage module SM by the transfer robots TR1 and TR2. The vacuum transfer module TM2 and the storage module SM are separated by a gate valve G4 that can be opened and closed.

The processing system PS includes a controller CU. The controller CU controls individual components of the processing system, such as the transfer robots TR1 and TR2 respectively disposed in the vacuum transfer modules TM1 and TM2, the transfer robot disposed in the atmospheric transfer module LM, and the gate valves G1 to G4. For example, the controller CU is configured to select a simultaneous transfer mode in which the transfer robots TR1 and TR2 simultaneously transfer the edge ring FR and the cover ring CR or a single transfer mode in which the transfer robots TR1 and TR2 transfer only the edge ring FR. The simultaneous transfer mode and the single transfer mode will be described later.

The controller CU may be, e.g., a computer. The controller CU includes a central processing unit (CPU), a random access memory (RAM), a read only memory (ROM), an auxiliary storage device, and the like. The CPU operates based on a program stored in the ROM or the auxiliary storage device, and controls the individual components of the processing system PS.

(Plasma Processing Apparatus)

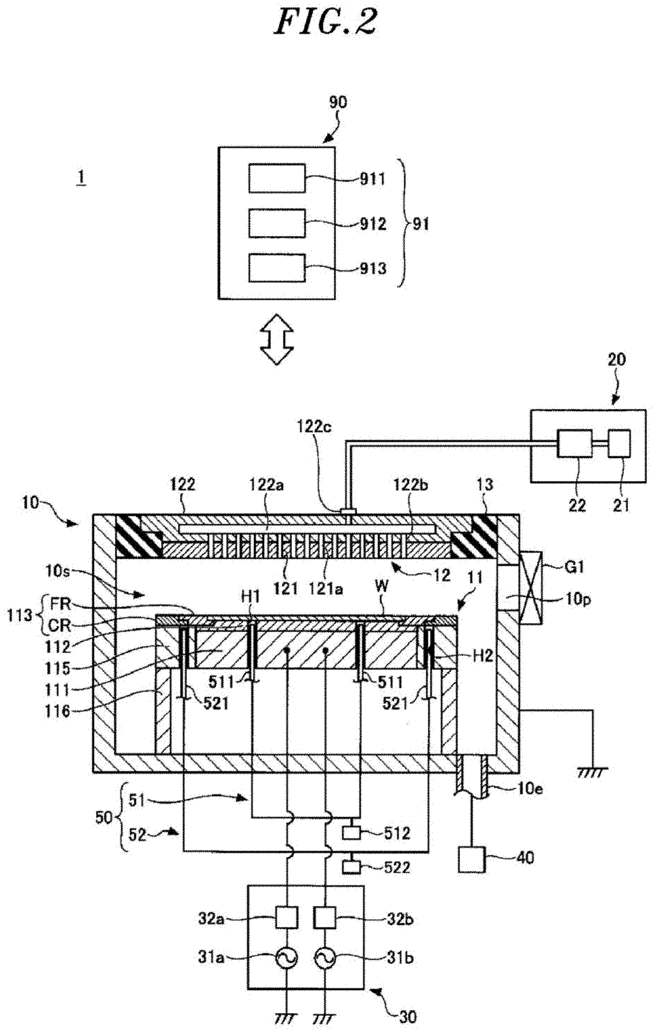

An example of a plasma processing apparatus used as the process modules PM1 to PM12 of the processing system PS of FIG. 1 will be described with reference to FIG. 2.

The plasma processing apparatus 1 includes a plasma processing chamber 10, a gas supplier 20, an RF power supplier 30, an exhaust system 40, an elevating mechanism 50, and a controller 90.

The plasma processing chamber 10 includes a substrate support 11 and an upper electrode 12. The substrate support 11 is disposed in a lower region of a plasma processing space 10s in the plasma processing chamber 10. The upper electrode 12 is disposed above the substrate support 11 and may function as a part of a ceiling plate of the plasma processing chamber 10.

The substrate support 11 supports the substrate W in the processing space 10s. The substrate support 11 includes a lower electrode 111, an electrostatic chuck 112, a ring assembly 113, an insulator 115, and a base 116. The electrostatic chuck 112 is disposed on the lower electrode 111. The electrostatic chuck 112 supports the substrate W on an upper surface thereof. The ring assembly 113 includes an edge ring FR and a cover ring CR. The edge ring FR has a ring shape and is disposed around the substrate W on an upper surface of a peripheral portion of the lower electrode 111. The edge ring FR improves, for example, uniformity of plasma processing. The cover ring CR has a ring shape and is disposed at an outer peripheral portion of the edge ring FR. The cover ring 114 protects, for example, an upper surface of the insulator 115 from plasma. In the example of FIG. 2, the outer peripheral portion of the edge ring FR is placed on an inner peripheral portion of the cover ring CR. Accordingly, when a plurality of support pins 521 to be described later are raised and lowered, the cover ring CR and the edge ring FR are raised and lowered as a unit. The insulator 115 is disposed on the base 116 to surround the lower electrode 111. The base 116 is fixed to the bottom portion of the chamber 10 and supports the lower electrode 111 and the insulator 115. The ring shape includes an annular shape.

The upper electrode 12 constitutes the plasma processing chamber 10 together with the insulating member 13. The upper electrode 12 supplies one or more processing gases from the gas supplier 20 to the plasma processing space 10s. The upper electrode 12 includes a ceiling plate 121 and a support body 122. A bottom surface of the ceiling plate 121 defines the processing space 10s. A plurality of gas injection holes 121a are formed in the ceiling plate 121. The plurality of gas injection holes 121a penetrate through the ceiling plate 121 in a plate thickness direction (vertical direction). The support body 122 detachably supports the ceiling plate 121. A gas diffusion space 122a is formed in the support body 122. A plurality of gas injection holes 122b extends downward from the gas diffusion space 122a. The plurality of gas injection holes 122b communicate with the plurality of gas injection holes 121a, respectively. A gas inlet 122c is formed in the support body 122. The upper electrode 12 supplies one or more processing gases from the gas inlet port 122c to the processing space 10s through the gas diffusion space 122a, the plurality of gas injection holes 122b, and the plurality of gas injection holes 121a.

A loading/unloading port 10p is formed on a sidewall of the plasma processing chamber 10. The substrate W is transferred between the processing space 10s and the outside of the plasma processing chamber 10 through the loading/unloading port 10p. The loading/unloading port 10p is opened and closed by the gate valve G1.

The gas supplier 20 includes one or more gas sources 21 and one or more flow rate controller 22. The gas supplier 20 supplies one or more processing gases from the gas sources 21 to the gas inlet port 122c through the flow rate controllers 22. The flow rate controllers 22 may include, e.g., a mass flow controller or a pressure-controlled flow rate controller. Further, the gas supplier 20 may include one or more flow rate modulation devices for modulating the flow rates of one or more processing gases or converting them into pulse form.

The RF power supplier 30 includes two RF power supplies (first RF power supply 31a and second RF power supply 31b) and two matching units (first matching unit 32a and second matching unit 32b). The first RF power supply 31a supplies a first RF power to the lower electrode 111 through the first matching unit 32a. The frequency of the first RF power may be within a range of, e.g., 13 MHz to 150 MHZ. The second RF power supply 31b supplies a second RF power to the lower electrode 111 through the second matching unit 32b. The frequency of the second RF power may be within a range of, e.g., 400 kHz to 13.56 MHz. A DC power supply may be used instead of the second RF power supply 31b.

The exhaust system 40 may be connected to, for example, an exhaust port 10e disposed at a bottom portion of the plasma processing chamber 10. The exhaust system 40 may include a pressure control valve and a vacuum pump. The pressure control valve adjusts a pressure in the plasma processing space 10s. The vacuum pump may include a turbo molecular pump, a dry pump, or a combination thereof.

The elevating mechanism 50 raises and lowers the substrate W, the edge ring FR, and the cover ring CR. The elevating mechanism 50 includes a first elevating mechanism 51 and a second elevating mechanism 52.

The first elevating mechanism 51 includes a plurality of support pins 511 and an actuator 512. The plurality of support pins 511 are inserted into through-holes H1 formed in the lower electrode 111 and the electrostatic chuck 112 to protrude and retract with respect to the upper surface of the electrostatic chuck 112. When the plurality of support pins 511 protrude from the upper surface of the electrostatic chuck 112, upper ends of the plurality of support pins 511 are in contact with a bottom surface of the substrate W to support the substrate W. The actuator 512 raises and lowers the support pins 511. The actuator 512 may be a motor such as a DC motor, a stepping motor, or a linear motor, an air driving mechanism, a piezo actuator, or the like. The first elevating mechanism 51 raises and lowers the plurality of support pins 511 to transfer the substrate W between the transfer robots TR1 and TR2 and the support 11, for example.

The second elevating mechanism 52 includes a plurality of support pins 521 and an actuator 522. The plurality of support pins 521 are inserted into through-holes H2 formed in the insulator 115 to protrude and retract with respect to the upper surface of the insulator 115. When the plurality of support pins 521 protrude from the upper surface of the insulator 115, upper ends of the support pins 521 are in contact with a bottom surface of the cover ring CR to support the cover ring CR. The actuator 522 raises and lowers the plurality of support pins 521. The actuator 522 may be the same as the actuator 512. The second elevating mechanism 52 raises and lowers the plurality of support pins 521 to transfer the edge ring FR and the cover ring CR between the transfer robots TR1 and TR2 and the substrate support 11, for example. In the example of FIG. 2, the outer peripheral portion of the edge ring FR is placed on the inner peripheral portion of the cover ring CR. Accordingly, when the plurality of support pins 521 are raised and lowered by the actuator 522, the cover ring CR and the edge ring FR are raised and lowered as a unit.

The controller 90 controls the individual components of the plasma processing apparatus 1. The controller 90 includes, e.g., a computer 91. The computer 91 includes, e.g., a CPU 911, a storage unit 912, a communication interface 913, and the like. The CPU 911 may be configured to perform various control operations based on the program stored in the storage unit 912. The storage unit 912 includes at least one type of memory selected from a group consisting of an auxiliary storage device such as a RAM, a ROM, a hard disk drive (HDD), a solid state drive (SSD), or the like. The communication interface 913 may communicate with the plasma processing apparatus 1 through a communication line such as a local area network (LAN) or the like. The controller 90 may be provided separately from the controller CU, or may be included in the controller CU.

(Storage Module)

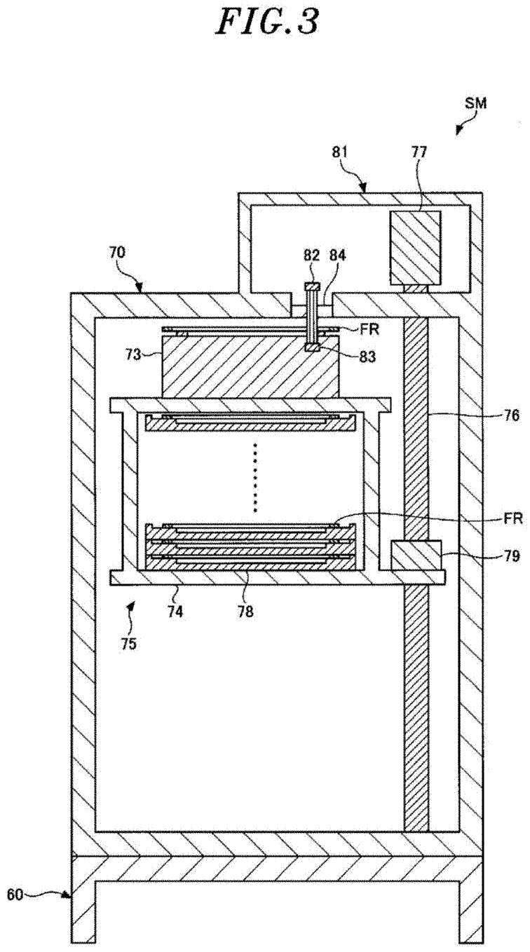

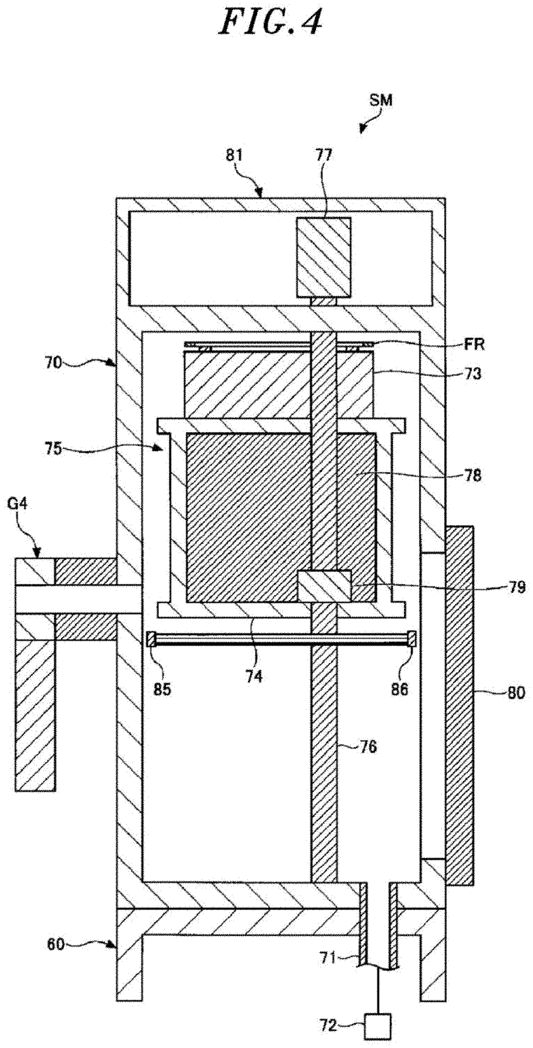

An example of the storage module SM of the processing system PS of FIG. 1 will be described with reference to FIGS. 3 and 4.

In the storage module SM, a chamber 70 is disposed on a frame 60 and a machine room 81 is disposed on the chamber 70. The chamber 70 can be depressurized by an exhaust 72 connected to an exhaust port 71 disposed at the bottom portion of the chamber 70. Further, N₂ gas is supplied as a purge gas to the chamber 70. Accordingly, a pressure in the chamber 70 can be adjusted. The machine room 81 is at an atmospheric pressure.

A storage 75 having a stage 73 and a basket 74 disposed below the stage 73 is installed in the chamber 70. The storage 75 can be raised and lowered by a ball screw 76. In the machine room 81, a line sensor 82 for detecting a position and a direction of the consumable part, and a motor 77 for driving the ball screw 76 are installed in the machine room 81. A window 84 made of quartz or the like is disposed between the chamber 70 and the machine room 81 so that the line sensor 82 can receive the light from a light emitting part 83 to be described later.

A consumable part is placed on the stage 73. The stage 73 comprises the light emitting part 83 facing the line sensor 82. The stage 73 is rotatable in a e direction, and rotates the consumable part placed thereon, e.g., the edge ring FR, in a predetermined direction. In other words, the stage 73 performs alignment (positioning) of the edge ring FR. In the alignment process, an orientation flat OF of the edge ring FR is aligned in a predetermined direction. Further, in the alignment process, a center position of the edge ring FR may be aligned.

The line sensor 82 detects the amount of light emitted from the light emitting part 83 and outputs the detected light amount to the controller CU. The controller CU detects the orientation flat of the edge ring FR based on the fact that the detected light amount changes depending on whether or not the orientation flat of the edge ring FR exists. The controller CU detects the direction of the edge ring FR based on the detected orientation flat. The line sensor 82 is, e.g., a line sensor such as a charge coupled device (CCD), a complementary metal oxide semiconductor (CMOS), or the like.

The basket 74 is disposed below the stage 73. A cassette 78 is disposed in the basket 74. The cassette 78 is a storage container that can be taken out from the basket 74. The cassette 78 comprises intervals in the vertical direction to accommodate a plurality of consumable parts. In the example of FIG. 3, a plurality of edge ring FRs are stored in the cassette 78. A front side of the storage module SM for the cassette 78 is opened. The cassette 78 will be described in detail later.

The storage 75 comprises a guide 79 supported by the ball screw 76 on a side surface thereof, in addition to the stage 73 and the basket 74. The ball screw 76 connects the upper surface and the bottom surface of the chamber 70, penetrates through the upper surface of the chamber 70, and is connected to the motor 77 in the machine room 81. The portion of the upper surface of the chamber 70 through which the ball screw 76 penetrates is sealed so that the ball screw 76 can rotate. The ball screw 76 can be rotated by the motor 77 to move the storage 75 in the vertical direction (Z-axis direction).

The storage module SM is detachably connected to the vacuum transfer module TM2 via the gate valve G4. The upper fork FK21 and the lower fork FK22 of the transfer robot TR2 of the vacuum transfer module TM2 can be inserted into the chamber 70 through the gate valve G4. The upper fork FK21 and the lower fork FK22 load the edge ring FR into the cassette 78, unload the edge ring FR loaded in the cassette 78, place the edge ring FR on the stage 73, and receive the edge ring FR placed on the stage 73. The door 80 is opened and closed when the cassette 78 is taken out from the chamber 70 and when the cassette 78 is installed in the chamber 70, for example.

The light emitting part 85 and the sheet number detection sensor 86 detect the number of edge rings FR placed in the cassette 78 when the storage 75 moves the cassette 78 from the bottom surface side of the chamber 70 to an upper position such as a position facing the gate valve G4 or the like. The light emitting part 85 is, e.g., a light emitting diode (LED), a semiconductor laser, or the like. The sheet number detection sensor 86 detects the amount of light emitted from the light emitting part 85, and outputs the detected light amount to the controller CU. The controller CU detects the number of edge rings FR by measuring the number of times in which the light emitted from the light emitting part 85 is blocked by the edge ring FR based on the detected light amount. The sheet number detection sensor 86 is, e.g., a photodiode, a phototransistor, or the like. Further, the sheet number detection sensor 86 may be, e.g., a line sensor such as a CCD, a CMOS, or the like.

In the above example, the case where the controller CU obtains position information of the edge ring FR based on the light amount detected by the line sensor 82 in the storage module SM has been described. However, the present disclosure is not limited thereto. For example, a position detection sensor including an inner circumference sensor for detecting a position of an inner circumference of the edge ring FR and an outer circumference sensor for detecting a position of an outer circumference of the edge ring FR may be used. In this case, the controller CU obtains the position information of the edge ring FR based on the position of the inner circumference of the edge ring FR detected by the inner circumference sensor and the position of the outer circumference of the edge ring FR detected by the outer circumference sensor. Further, another optical sensor or a camera may be used instead of the line sensor 82. In this case, the controller CU obtains the position information of the edge ring FR based on an image captured by the camera by, e.g., using an image processing technique.

(Transfer Robot)

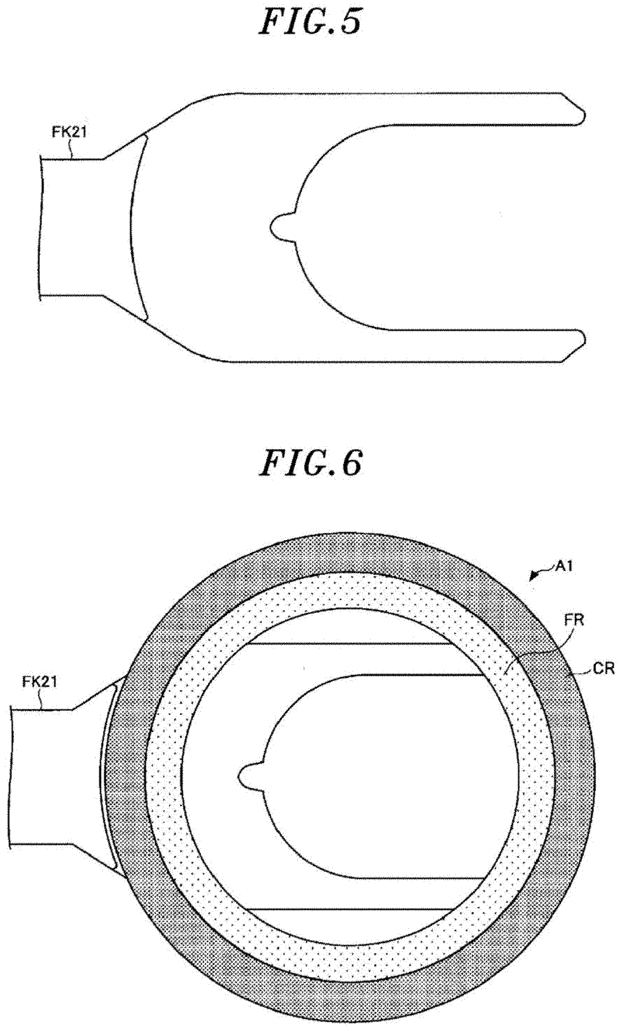

The upper fork FK21 of the transfer robot TR2 will be described with reference to FIGS. 5 to 8. The lower fork FK22 of the transfer robot TR2 may have the same configuration as that of the upper fork FK21. Further, the upper fork FK11 and the lower fork FK12 of the transfer robot TR1 may have the same configuration as that of the upper fork FK21 of the transfer robot TR2.

FIG. 5 is a schematic plan view showing the upper fork FK21 that is not holding an object to be transferred. As shown in FIG. 5, the upper fork FK21 has a substantially U-shape in plan view. The upper fork FK21 is configured to hold a substrate W, a transfer jig CJ, an edge ring FR, a cover ring CR, a first assembly A1, and a second assembly A2, for example.

The transfer jig CJ is a jig that supports the edge ring FR from the bottom, and can be used in the case of replacing only the edge ring FR.

The first assembly A1 is an assembly in which the edge ring FR and the cover ring CR are integrated by placing the edge ring FR on the cover ring CR.

The second assembly A2 is an assembly in which the transfer jig CJ and the edge ring FR are integrated by placing the edge ring FR on the transfer jig CJ.

FIG. 6 is a schematic plan view showing the upper fork FK21 holding the first assembly A1 (the edge ring FR and the cover ring CR). As shown in FIG. 6, the upper fork FK21 is configured to hold the first assembly A1. Accordingly, the transfer robot TR2 can simultaneously transfer the edge ring FR and the cover ring CR.

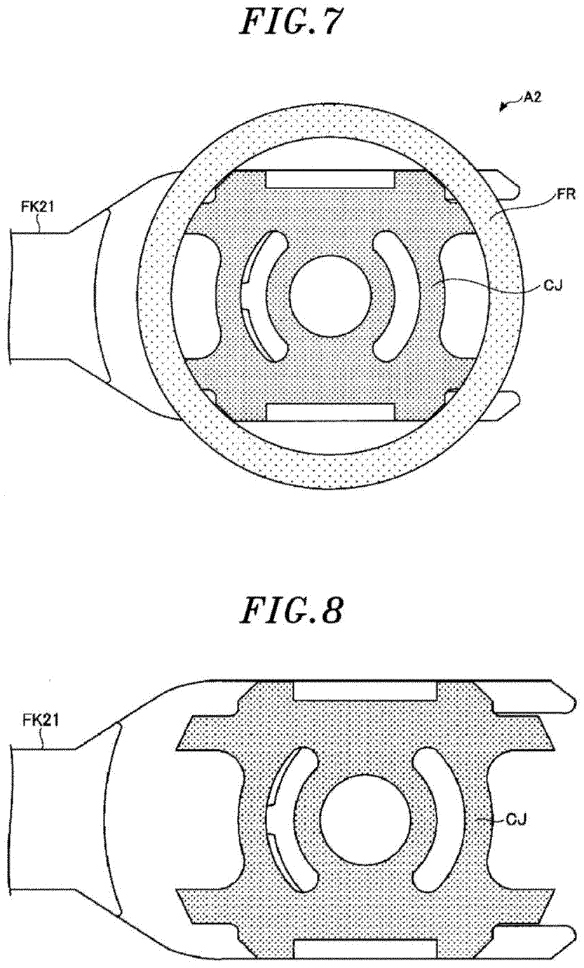

FIG. 7 is a schematic plan view showing the upper fork FK21 holding the second assembly A2 (the transfer jig CJ and the edge ring FR). As shown in FIG. 7, the upper fork FK21 is configured to hold the second assembly A2. Accordingly, the transfer robot TR2 can simultaneously transfer the transfer jig CJ and the edge ring FR.

FIG. 8 is a schematic plan view showing the upper fork FK21 holding only the transfer jig CJ. As shown in FIG. 8, the upper fork FK21 is configured to hold the transfer jig CJ that is not supporting the edge ring FR. Accordingly, the transfer robot TR2 can transfer the transfer jig CJ alone.

(Cassette)

Referring further to FIG. 9, the cassette 78 accommodating the edge rings FR will be described as an example of the cassette 78 of the storage module SM. FIG. 9 is a schematic perspective view showing an example of the cassette 78 in the storage module SM. Further, FIG. 9 shows the cassette 78 in a state where the edge rings FR are not accommodated.

The cassette 78 accommodates the edge rings FR. The cassette 78 comprises a plurality of base plates 781 and a plurality of guide pins 782.

The plurality of base plates 781 are arranged in multiple stages in the vertical direction. The plurality of base plates 781 place the edge rings FR thereon. Each of the base plates 781 has a substantially rectangular plate shape. Each of the base plates 781 is made of, e.g., resin or a metal. Each of the base plates 781 includes a placement surface 781a, an outer frame portion 781b and a fork insertion groove 781c.

The edge ring FR is placed on the placement surface 781a.

The outer frame portion 781b projects upward from the placement surface 781a at outer peripheral portions of three sides of the placement surface 781a, except for a front side into which the upper fork FK21 and the lower fork FK22 are inserted, among the four sides of the placement surface 781a. Another base plate 781 is placed on the outer frame portion 781b.

The fork insertion groove (recess) 781c is formed on the placement surface 781a. The fork insertion groove 781c is recessed with respect to the placement surface 781a, and the upper fork FK21 and the lower fork FK22 are inserted into the fort insertion groove 781c when the transfer robot TR2 places the edge ring FR on the placement surface 781a.

The plurality of guide pins 782 are disposed on the placement surface 781a. Each of the guide pins 782 may have a conical shape tapering toward an end. When the transfer robot TR2 places the edge ring FR on the placement surface 781a, the guide pins 782 are brought into contact with the outer peripheral portion of the edge ring FR and guide the edge ring FR to be placed at a predetermined position on the placement surface 781a. Each of the guide pins 782 may be made of resin, a metal, or the like. In case of resin, it is possible to suppress generation of particles caused by the contact with the outer peripheral portion of the edge ring FR.

Although FIG. 9 illustrates a cassette 78 accommodating the edge rings FR, a cassette 78 accommodating, for example, the transfer jigs CJ, the cover rings CR, the first assemblies A1, and the second assemblies A2 may also have the same configuration as that of the cassette 78 of FIG. 9, except for the guide pins 782.

For example, in the cassette 78 accommodating the cover rings CR, the plurality of guide pins 782 are disposed at positions to be in contact with the inner peripheral portion of the cover ring CR placed on the placement surface 781a by the transfer robot TR2. Accordingly, the cover ring CR is guided to be placed at predetermined positions on the placement surface 781a.

For example, in the cassette 78 accommodating the edge rings FR and the cover rings CR, the plurality of guide pins 782 are disposed at positions to be in contact with the outer peripheral portion of the edge ring FR and the inner peripheral portion of the cover ring CR placed on the placement surface 781a by the transfer robot TR2. Accordingly, the edge ring FR and the cover ring CR are guided to be placed at predetermined positions on the placement surface 781a.

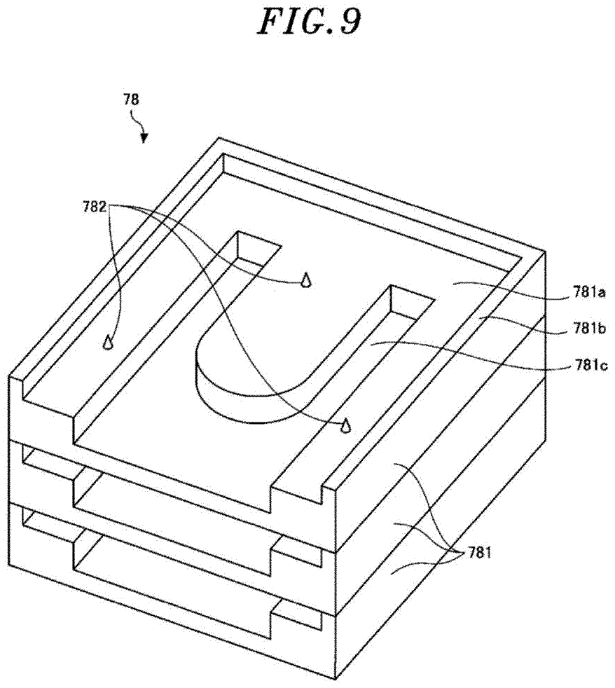

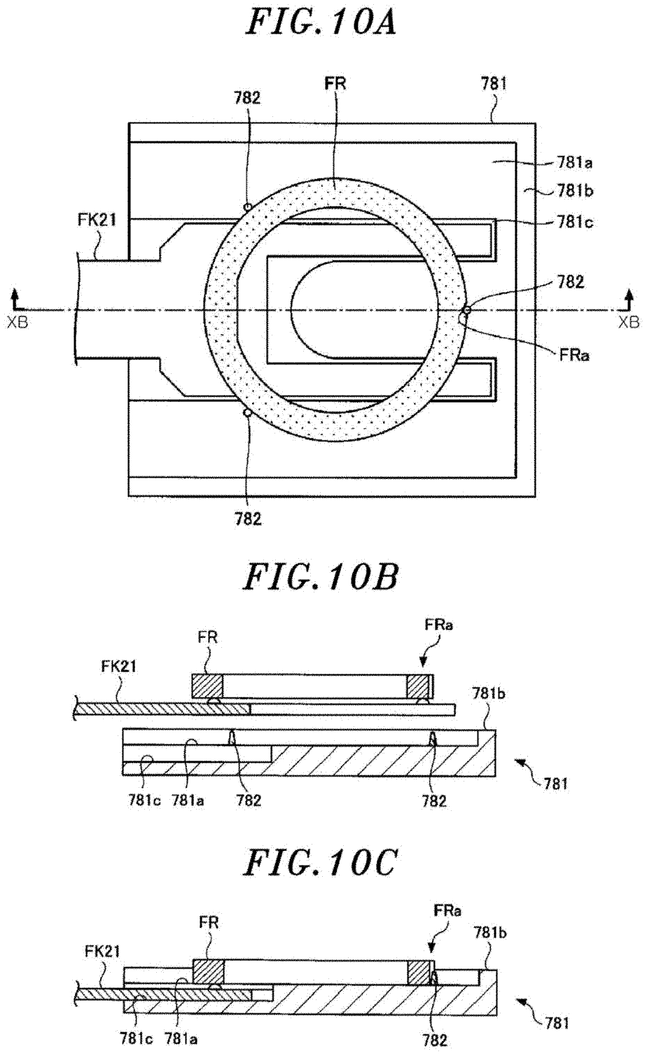

An example of a positioning mechanism used in the case of placing the edge ring FR transferred into the storage module SM by the upper fork FK21 on the base plate 781 of the cassette 78 will be described with reference to FIGS. 10A to 10C. FIGS. 10A to 10C show an example of the positioning mechanism for the edge ring FR. FIG. 10A is a top view showing a state in which the upper fork FK21 holding the edge ring FR is positioned above the base plate 781. FIG. 10B shows a cross section taken along a dashed-dotted line XB-XB in FIG. 10A. FIG. 10C is a cross-sectional view showing a state in which the edge ring FR is placed on the base plate 781 by the upper fork FK21.

First, as shown in FIGS. 10A and 10B, the edge ring FR comprises a notch FRa at an outer circumference thereof. The upper fork FK21 holding the edge ring FR is positioned above the base plate 781. The notch FRa has, for example, a V shape in plan view. An opening angle of the V shape may be appropriately set, and may be, e.g., 90°. Further, the notch FRa may have a curved shape such as a U shape or the like in plan view, for example.

Next, as shown in FIG. 10C, the upper fork FK21 is lowered. Accordingly, the edge ring FR held on the upper fork FK21 is placed on the placement surface 781a of the base plate 781. In this case, one of the three guide pins 782 is engaged with the notch FRa of the edge ring FR, and the other two guide pins 782 are brought into contact with the outer circumference of the edge ring FR, thereby positioning the edge ring FR. Accordingly, the edge ring FR can be positioned with respect to the base plate 781 in a horizontal direction and a rotation direction.

In this manner, the edge ring FR can be positioned by placing the edge ring FR on the base plate 781 using the upper fork FK21. Therefore, the positioned edge ring FR can be transferred to the process modules PM1 to PM12 without separately providing an alignment mechanism for positioning the edge ring FR. As a result, the downtime caused by transferring the edge ring FR to the alignment mechanism can be reduced. Further, the device introduction cost can be saved. In addition, the space efficiency can be improved. However, it is also possible to separately provide an alignment mechanism, precisely position the edge ring FR using the alignment mechanism, and transfer the positioned edge ring FR.

In the example of FIGS. 10A to 10C, the case where the edge ring FR comprises one notch FRa at the outer circumference thereof is illustrated. However, the number of the notch FRa is not limited thereto. For example, the edge ring FR may comprise a plurality of notches Fra spaced apart from each other in a circumferential direction at the outer circumference thereof. In that case, it is preferable that the guide pins 782 are disposed to correspond to the plurality of notches Fra, respectively. Accordingly, an angle error can be reduced.

Further, although the examples of FIGS. 10A to 10C illustrate the case where the upper fork FK21 is used, the lower fork FK22 may be used.

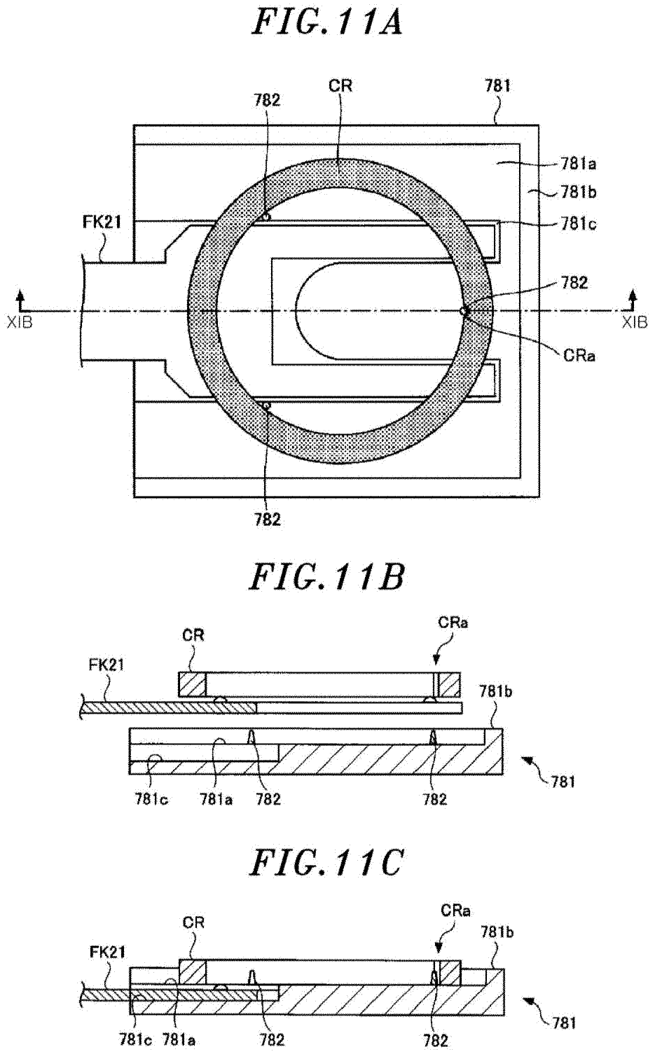

An example of a positioning mechanism used in the case of placing the cover ring CR transferred into the storage module SM by the upper fork FK21 on the base plate 781 of the cassette 78 will be described with reference to FIGS. 11A to 11C. FIGS. 11A to 11C show an example of the positioning mechanism of the cover ring CR. FIG. 11A is a top view showing a state in which the upper fork FK21 holding the cover ring CR is located above the base plate 781. FIG. 11B shows a cross section taken along a dashed-dotted line XIB-XIB in FIG. 11A. FIG. 11C is a cross-sectional view showing a state in which the cover ring CR is placed on the base plate 781 by the upper fork FK21.

First, as shown in FIGS. 11A and 11B, the cover ring CR comprises a notch CRa at its inner circumference thereof. The upper fork FK21 holding the cover ring CR is positioned above the base plate 781. The notch CRa has, for example, a V shape in plan view. An opening angle of the V shape may be appropriately set, and may be, e.g., 90°. Further, the notch CRa may have a curved shape such as a U shape or the like in plan view.

Then, as shown in FIG. 11C, the upper fork FK21 is lowered. Accordingly, the cover ring CR held on the upper fork FK21 is placed on the placement surface 781a of the base plate 781. In this case, one of the three guide pins 782 is engaged with the notch CRa of the cover ring CR, and the other two guide pins 782 are brought into contact with the inner circumference of the cover ring CR to position the cover ring CR. As a result, the cover ring CR can be positioned with respect to the base plate 781 in the horizontal direction and the rotation direction.

In this manner, the cover ring CR can be positioned by placing the cover ring CR on the base plate 781 using the upper fork FK21. Therefore, the positioned cover ring CR can be transferred to the process modules PM1 to PM12 without separately providing an alignment mechanism for positioning the cover ring CR. As a result, the downtime caused by transferring the cover ring CR to the alignment mechanism can be reduced. Further, the device introduction cost can be saved. In addition, the space efficiency is improved. However, it is also possible to separately provide an alignment mechanism, precisely position the cover ring CR using the alignment mechanism, and transfer the positioned cover ring CR.

In the example of FIGS. 11A and 11B, the case where the cover ring CR comprises one notch CRa at the inner circumference thereof is illustrated. However, the number of the notch CRa is not limited thereto. For example, the cover ring CR may comprise a plurality of notches CRa spaced apart from each other in the circumferential direction at the inner circumference thereof. In that case, it is preferable that the guide pins 782 are disposed to correspond to the plurality of notches CRa, respectively. Accordingly, the angle error can be reduced.

Further, although the example of FIGS. 11A and 11B illustrates the case where the upper fork FK21 is used, the lower fork FK22 may be used.

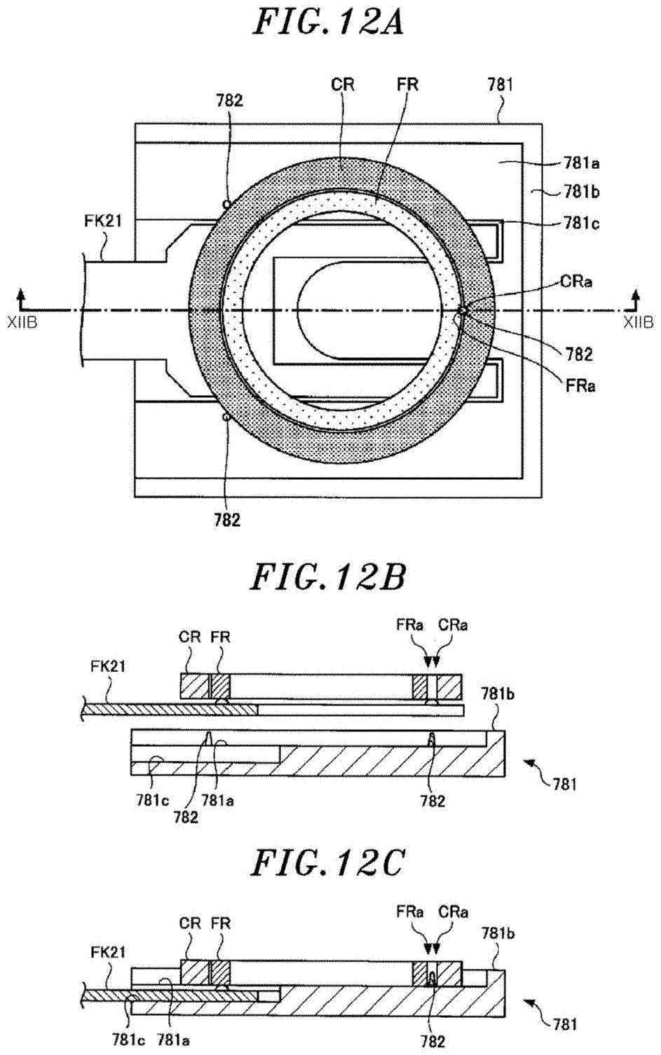

A positioning mechanism used in the case of placing the edge ring FR and the cover ring CR transferred into the storage module SM using the upper fork FK21 on the base plate 781 of the cassette 78 will be described with reference to FIGS. 12A to 12C. FIGS. 12A to 12C show an example of the positioning mechanism for the edge ring FR and the cover ring CR. FIG. 12A is a top view showing a state in which the upper fork FK21 holding the edge ring FR and the cover ring CR is positioned above the base plate 781. FIG. 12B shows a cross section taken along a dashed-dotted line XIIB-XIIB in FIG. 12A. FIG. 12C is a cross-sectional view showing a state in which the edge ring FR and the cover ring CR are placed on the base plate 781 by the upper fork FK21.

First, as shown in FIGS. 12A and 12B, the upper fork FK21 holding the edge ring FR and the cover ring CR is positioned above the base plate 781. The outer peripheral portion of the edge ring FR and the inner peripheral portion of the cover ring CR do not overlap in plan view. In other words, an outer diameter of the edge ring FR is smaller than or equal to an inner diameter of the cover ring CR. The edge ring FR comprises a notch FRa at the outer circumference thereof. The cover ring CR comprises a notch CRa at the inner circumference thereof. The notches FRa and CRa have, for example, a V shape in plan view. An opening angle of the V shape may be appropriately set, and may be, e.g., 90°. Further, the notches FRa and CRa may have a curved shape such as a U shape or the like in plan view.

Next, as shown in FIG. 12C, the upper fork FK21 is lowered. Accordingly, the edge ring FR and the cover ring CR held on the upper fork FK21 are placed on the placement surface 781a of the base plate 781. In this case, one of the three guide pins 782 is engaged with the notch FRa of the edge ring FR and the notch CRa of the cover ring CR, and the other two guide pins 782 are brought into contact with the outer circumference of the cover ring CR, thereby positioning the edge ring FR and cover ring CR. As a result, the edge ring FR and the cover ring CR can be positioned with respect to the base plate 781 in the horizontal direction and the rotation direction.

In this manner, the edge ring FR and the cover ring CR can be positioned by placing the edge ring FR and the cover ring CR on the base plate 781 using the upper fork FK21. Therefore, the positioned edge ring FR and the positioned cover ring CR can be transferred to the process modules PM1 to PM12 without separately providing an alignment mechanism for positioning the edge ring FR and the cover ring CR. As a result, the downtime caused by transferring the edge ring FR and the cover ring CR to the alignment mechanism can be reduced. Further, the device introduction cost can be saved. In addition, the space efficiency can be improved. However, it is also possible to separately provide an alignment mechanism and transfer the edge ring FR and the cover ring CR that are precisely positioned by the alignment mechanism.

In the example of FIG. 12A to 12C, the case where the edge ring FR comprises one notch FRa at the outer circumference thereof and the cover ring CR comprises one notch CRa at the inner circumference thereof is illustrated. However, the numbers of the notches FRa and CRa are not limited thereto. For example, the edge ring FR may comprise a plurality of notches FRa spaced apart from each other in the circumferential direction at the outer circumference thereof, and the cover ring CR may comprise a plurality of notches CRa spaced apart from each other in the circumferential direction at the inner circumference thereof. In that case, it is preferable that the guide pins 782 are disposed to correspond to the notches FRa and CRa, respectively. Accordingly, an angle error can be reduced.

Further, although the example of FIGS. 12A to 12C illustrates the case where the upper fork FK21 is used is illustrated, the lower fork FK22 may be used.

Further, in the example of FIGS. 12A to 12C, the case where the edge ring FR and the cover ring CR are positioned at the outer circumference or the inner circumference thereof has been described. However, the present disclosure is not limited thereto. For example, positioning recesses (or protrusions) may be formed on the back surfaces (the surfaces to be placed on the placement surface 781a) of the edge ring FR and the cover ring CR so that the edge ring FR and the cover ring CR can be positioned.

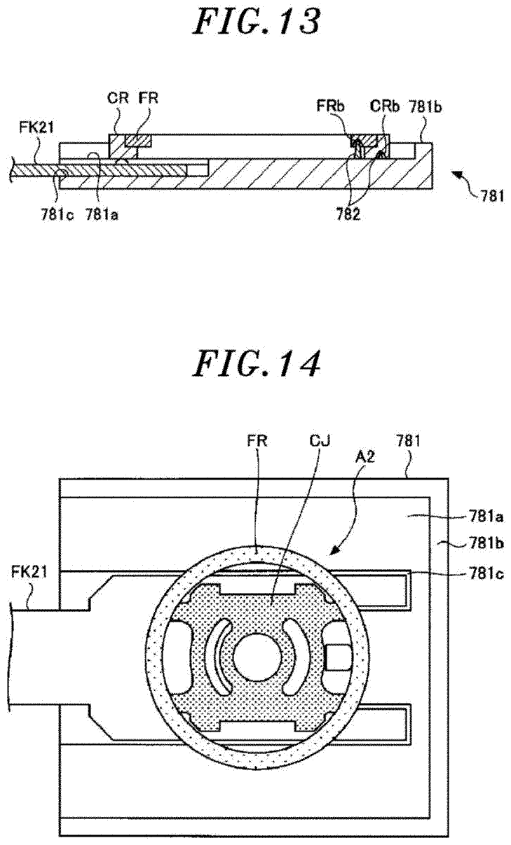

Further, in the example of FIGS. 12A to 12C, the case where the outer peripheral portion of the edge ring FR and the inner peripheral portion of the cover ring CR do not overlap has been described. However, the present disclosure is not limited thereto, and the outer peripheral portion of the edge ring FR and the inner peripheral portion of the cover ring CR may overlap. In that case, the edge ring FR may be held in a positioned state with respect to the cover ring CR. In one example, the edge ring FR may be positioned by positioning the cover ring CR using a positioning portion formed at the outer circumference of the cover ring CR. In another example, when the outer peripheral portion of the edge ring FR and the inner peripheral portion of the cover ring CR overlap, positioning recesses FRb and CRb (or protrusions) may be formed at the areas where the edge ring FR and the cover ring CR do not overlap as shown in FIG. 13. In that case, the guide pins 782 may be disposed to be engaged with the recesses FRb and CRb. Accordingly, each of the edge ring FR and the cover ring CR can be positioned.

Although the case where the edge ring FR and/or the cover ring CR is placed on the base plate 781 of the cassette 78 using the upper fork FK21 has been described with reference to FIGS. 10 to 13, the present disclosure is not limited thereto. For example, an operator may manually place the edge ring FR and/or the cover ring CR on the base plate 781 of the cassette 78 when the storage module SM is not in operation.

A case where the second assembly A2 (the transfer jig CJ and the edge ring FR) transferred into the storage module SM by the upper fork FK21 is placed on the base plate 781 of the cassette 78 will be described with reference to FIG. 14. The operation shown in FIG. 14 is performed, e.g., when the outer peripheral portion of the edge ring FR and the inner peripheral portion of the cover ring CR placed on the electrostatic chuck 112 of the plasma processing apparatus 1 overlap and the controller CU selects and executes the single transfer mode to be described later. FIG. 14 is a schematic top view showing an example of the second assembly A2 accommodated in the cassette 78.

First, as shown in FIG. 14, the upper fork FK21 holding the second assembly A2 is positioned above the base plate 781. Then, the upper fork FK21 is lowered. Accordingly, the second assembly A2 held on the upper fork FK21 is placed on the placement surface 781a of the base plate 781.

In this manner, the transfer robot TR2 can hold the second assembly A2 (the transfer jig CJ and the edge ring FR) using the upper fork FK21 and simultaneously transfer the transfer jig CJ and the edge ring FR.

Although the example of FIG. 14 illustrates the case where the upper fork FK21 is used, the lower fork FK22 may be used.

A case where the transfer jig CJ transferred into the storage module SM by the upper fork FK21 is placed on the base plate 781 of the cassette 78 will be described with reference to FIG. 15. The operation shown in FIG. 15 is performed, e.g., when the outer peripheral portion of the edge ring FR and the inner peripheral portion of the cover ring CR placed on the electrostatic chuck 112 of the plasma processing apparatus 1 overlap and the controller CU selects and executes the single transfer mode to be described later. FIG. 15 is a schematic plan view showing an example of the transfer jig CJ accommodated in the cassette 78.

First, as shown in FIG. 15, the upper fork FK21 holding the transfer jig CJ is positioned above the base plate 781. Then, the upper fork FK21 is lowered. Accordingly, the transfer jig CJ held by the upper fork FK21 is placed on the placement surface 781a of the base plate 781.

In this manner, the transfer robot TR2 can hold the transfer jig CJ using the upper fork FK21 and transfer the transfer jig CJ alone.

Although the example of FIG. 15 illustrates the case where the upper fork FK21 is used, the lower fork FK22 may be used.

Another example of the cassette 78 included in the storage module SM of FIGS. 3 and 4 will be described with reference to FIG. 16. FIG. 16 is a schematic perspective view showing another example of the cassette 78 in the storage module SM, and shows a cassette 78X accommodating the edge rings FR that is an example of the consumable part.

The cassette 78X shown in FIG. 16 is different from the cassette 78 shown in FIG. 9 in that it comprises inclined blocks 782b, each having an inclined surface to be in contact with the outer peripheral portion of the edge ring FR to hold the edge ring FR at a predetermined position, instead of the guide pins 782. The other configurations may be the same as those of the cassette 78 shown in FIG. 9.

In still another example, the cassette 78 may comprise inclined blocks (not shown), each having an inclined surface to be in contact with the inner peripheral portion of the cover ring CR to hold the cover ring CR at a predetermined position. In further still another example, the cassette 78 may comprise inclined blocks (not shown) having inclined surfaces to be in contact with the outer peripheral portion of the edge ring FR and the inner peripheral portion of the cover ring CR to hold the edge ring FR and the cover ring CR at predetermined positions. Further, the inclined blocks may be configured to be in contact with the inner peripheral portion of the edge ring FR to hold the edge ring FR at a predetermined position. Further, the inclined blocks may be configured to be in contact with the outer peripheral portion of the cover ring CR to hold the cover ring CR.

(Method of Transferring Consumable Part)

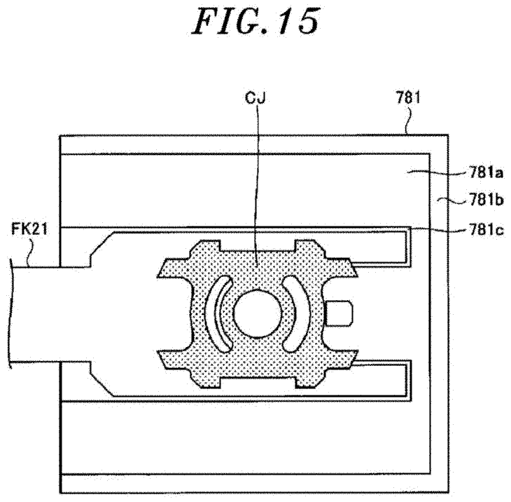

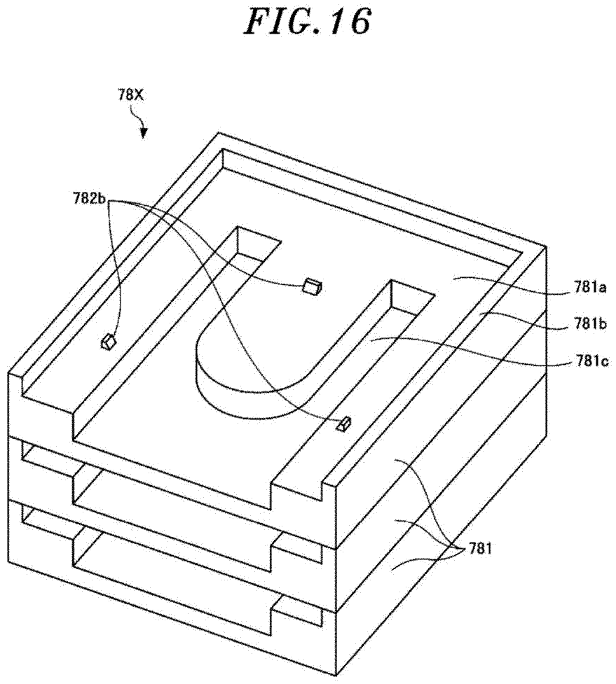

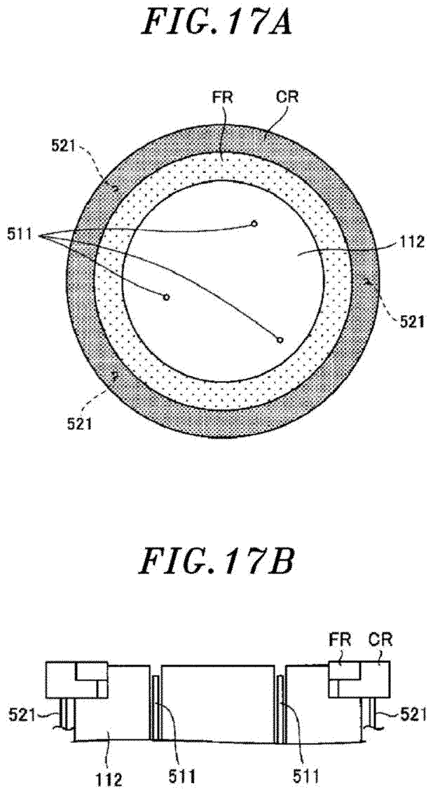

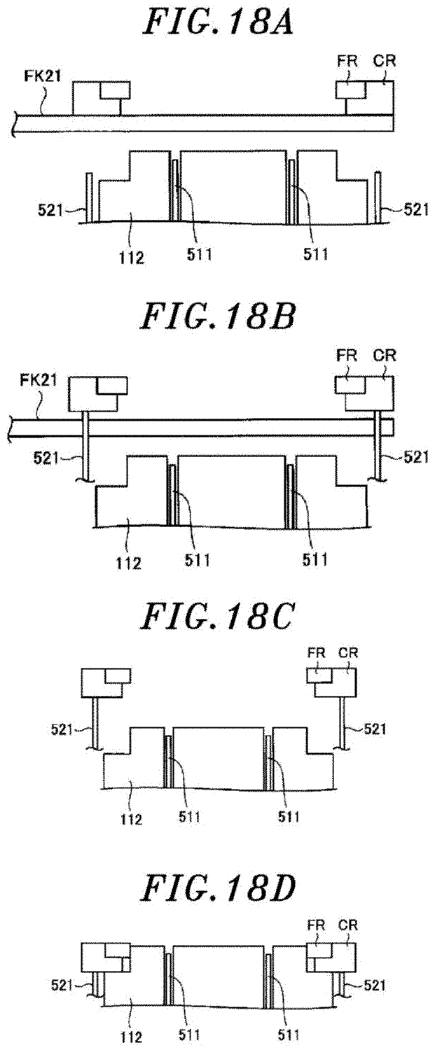

A case where the controller CU selects a simultaneous transfer mode in which the transfer robot TR2 simultaneously transfers the edge ring FR and the cover ring CR will be described, as an example of a method of transferring a consumable part in the processing system PS according to an embodiment, with reference to FIGS. 17A and 17B and 18A and 18B. In the following description, it is assumed that the controller 90 is included in the controller CU, and the controller CU controls the transfer robot TR2 and the elevating mechanism 50. However, the controller 90 may be provided separately from the controller CU so that the controller CU controls the transfer robot TR2 and the controller 90 controls the elevating mechanism 50. Further, it is assumed that the outer peripheral portion of the edge ring FR and the inner peripheral portion of the cover ring CR overlap in plan view.

As shown in FIG. 18A, the controller CU allows the upper fork FK21 holding an unused edge ring FR and an unused cover ring CR to be positioned above the electrostatic chuck 112.

Then, as shown in FIG. 18B, the controller CU raises the plurality of support pins 521 from a standby position to a support position. Accordingly, the upper ends of the plurality of support pins 521 are brought into contact with the bottom surface of the cover ring CR held on the upper fork FK21, and the cover ring CR is lifted by the support pins 521, thereby separating the cover ring CR from the upper fork FK21. In this case, since the outer peripheral portion of the edge ring FR is placed on the inner peripheral portion of the cover ring CR, the edge ring FR is lifted together with the cover ring CR when the cover ring CR is lifted by the plurality of support pins 521. In other words, the edge ring FR and the cover ring CR are separated as a unit from the upper fork FK21.

Next, as shown in FIG. 18C, the controller CU retracts the upper fork FK21 that is not holding an object to be transferred.

Then, as shown in FIG. 18D, the controller CU lowers the plurality of support pins 521 from the support position to the standby position. Accordingly, the edge ring FR and the cover ring CR supported by the plurality of support pins 521 are placed on the electrostatic chuck 112. In this manner, the edge ring FR and the cover ring CR are simultaneously loaded into the plasma processing chamber 10 and placed on the electrostatic chuck 112 as shown in FIGS. 17A and 17B.

In the case of unloading the edge ring FR and the cover ring CR placed on the electrostatic chuck 112 from the plasma processing chamber 10, the controller CU executes the above-described operation of loading the edge ring FR and the cover ring CR in a reverse order.

As described above, in accordance with the processing system PS of the embodiment, the edge ring FR and the cover ring CR can be transferred simultaneously.

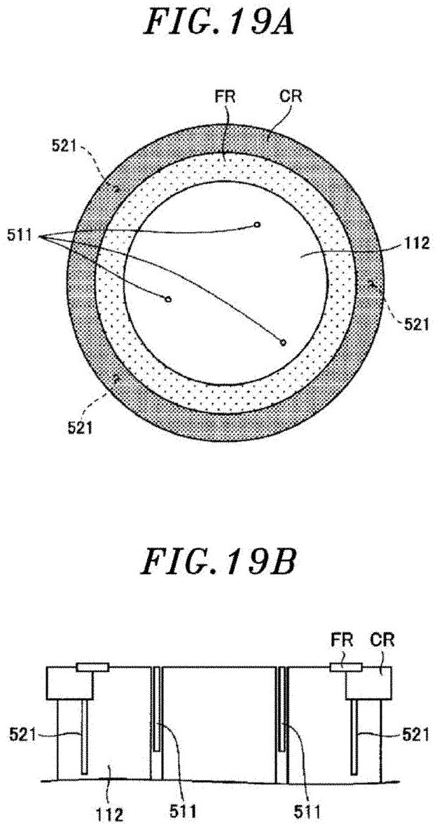

As another example of the method of transferring a consumable part in the processing system PS according to the embodiment, a case where the controller CU selects and executes the single transfer mode in which the transfer robot TR2 transfers only the edge ring FR will be described with reference to FIGS. 19A and 19B, 20A to 20D, and 21A to 21D. In the following description, it is assumed that the controller 90 is included in the controller CU, and the controller CU controls the transfer robot TR2 and the elevating mechanism 50. However, the controller 90 may be provided separately from the controller CU so that the controller CU controls the transfer robot TR2, and the controller 90 controls the elevating mechanism 50. Further, it is assumed that the outer peripheral portion of the edge ring FR and the inner peripheral portion of the cover ring CR overlap in plan view.

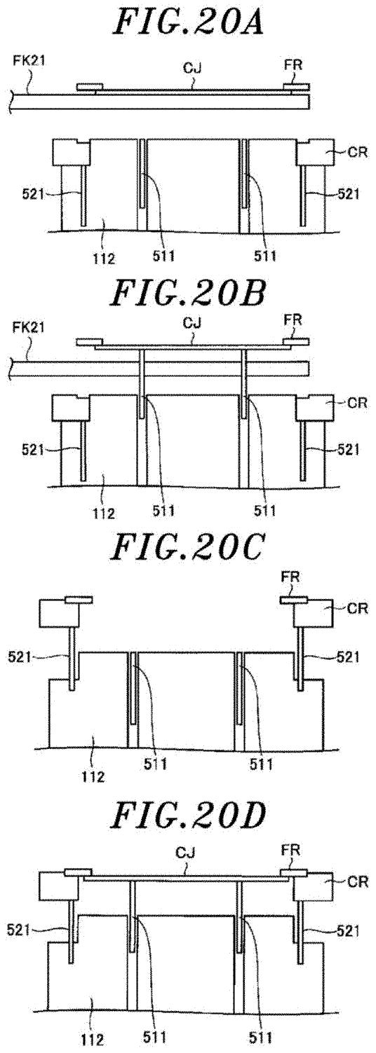

As shown in FIG. 20A, the controller CU allows the upper fork FK21 holding the transfer jig CJ holding the unused edge ring FR to be positioned above the electrostatic chuck 112.

Then, as shown in FIG. 20B, the controller CU raises the plurality of support pins 511 from the standby position to the support position. Accordingly, the upper ends of the plurality of support pins 511 are brought into contact with the bottom surface of the transfer jig CJ held by the upper fork FK21, and the transfer jig CJ is lifted by the support pins 511 and separated from the upper fork FK21. In this case, since the inner peripheral portion of the edge ring FR is placed on the transfer jig CJ, the edge ring FR is lifted together with the transfer jig CJ when the transfer jig CJ is lifted by the plurality of support pins 511. In other words, the transfer jig CJ and the edge ring FR are separated as a unit from the upper fork FK21.

Next, as shown in FIG. 20C, the controller CU retracts the upper fork FK21 that is not holding an object to be transferred.

Next, as shown in FIG. 20D, the controller CU raises the plurality of support pins 521 from the standby position to the support position. Accordingly, the upper ends of the plurality of support pins 521 are brought into contact with the bottom surface of the cover ring CR placed on the electrostatic chuck 112, and the cover ring CR is lifted by the plurality of support pins 521 and separated from the electric chuck 112. Further, the outer peripheral portion of the edge ring FR placed on the transfer jig CJ is placed on the inner peripheral portion of the cover ring CR.

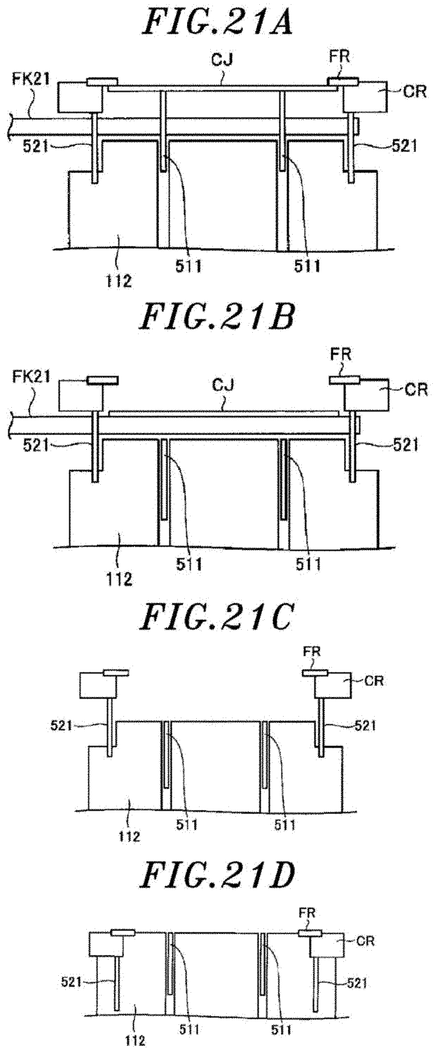

Then, as shown in FIG. 21A, the controller CU allows the upper fork FK21 that is not holding an object to be transferred to be positioned between the electrostatic chuck 112 and the transfer jig CJ, the edge ring FR, and the cover ring CR.

Then, as shown in FIG. 21B, the controller CU lowers the plurality of support pins 511 from the support position to the standby position. In this case, since the outer peripheral portion of the edge ring FR is placed on the inner peripheral portion of the cover ring CR, only the transfer jig CJ supported by the support pins 511 is placed on the upper fork FK21.

Then, as shown in FIG. 21C, the controller CU retracts the upper fork FK21 holding the transfer jig CJ.

Then, as shown in FIG. 21D, the controller CU lowers the plurality of support pins 521 from the support position to the standby position. Accordingly, the edge ring FR and the cover ring CR supported by the plurality of support pins 521 are placed on the electrostatic chuck 112. In this manner, only the edge ring FR is loaded into the plasma processing chamber 10 and placed on the electrostatic chuck 112 on which the cover ring CR is placed, as shown in FIGS. 19A and 19B.

In the case of unloading only the edge ring FR between the edge ring FR and the cover ring CR placed on the electrostatic chuck 112 from the plasma processing chamber 10, the controller CU executes the above-described operation of loading the edge ring FR and the cover ring CR in a reverse order.

As described above, in accordance with the processing system PS of the embodiment, only the edge ring FR can be transferred without replacing the cover ring CR.

(Method of Replacing a Consumable Part)

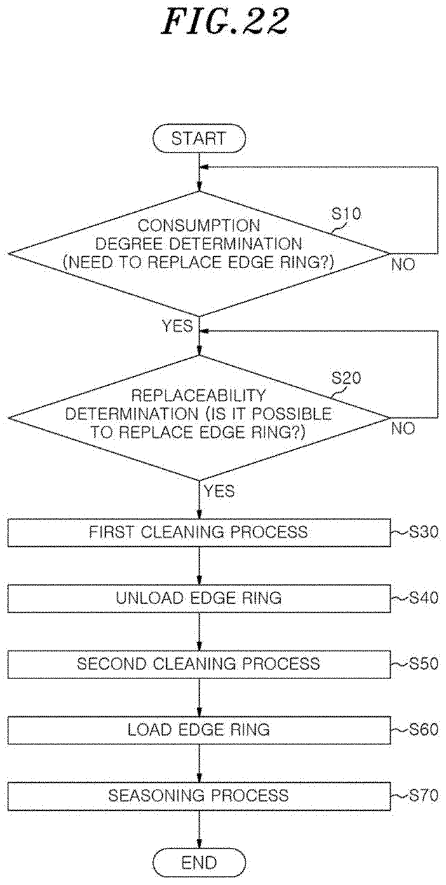

An example of a method of replacing a consumable part according to an embodiment will be described with reference to FIG. 22. FIG. 22 is a flowchart showing an example of the method of replacing a consumable part according to the embodiment.

Hereinafter, a case of replacing only the edge ring FR placed on the stage (the electrostatic chuck 112) of the above-described process module PM12 will be described as an example. Specifically, a case where the edge ring FR used in the process module PM12 is accommodated in the storage module SM and replaced with an unused edge ring FR in the storage module SM will be described. The edge rings FR placed on the stages of the process modules PM1 to PM11 other than the process module PM12 can also be replaced by the same method. Further, the method of replacing a consumable part according to the embodiment shown in FIG. 22 is performed by controlling the individual components of the processing system PS by the controller CU.

As shown in FIG. 22, the method of replacing a consumable part according to the embodiment includes a consumption degree determination step S10, a replaceability determination step S20, a first cleaning step S30, an unloading step S40, a second cleaning step S50, a loading step S60, and a seasoning step S70. Hereinafter, the respective steps will be described.

In the consumption degree determination step S10, it is determined whether or not the edge ring FR placed on the stage of the process module PM12 needs to be replaced. In the consumption degree determination step S10, the controller CU determines whether or not the edge ring FR placed on the stage of the process module PM12 needs to be replaced. Specifically, the controller CU determines whether or not the edge ring FR needs to be replaced based on, e.g., an RF integration time, an RF integration power, and an integrated value of a specific step of a recipe. The RF integration time is an integrated value of a time period in which an RF power is supplied in the process module PM12 during predetermined plasma processing. The RF integration power is an integrated value of the RF power supplied in the process module PM12 during the predetermined plasma processing. The integrated value of the specific step of the recipe is an integrated value of the RF power or an integrated value of the time period in which the RF power is supplied during, among the steps performed in the process module PM12, a step in which the edge ring FR is consumed. The RF integration time, the RF integration power, and the integrated value of the specific step of the recipe are calculated when the edge ring FR is replaced, e.g., when the device is introduced, when maintenance is performed, or the like.

In the case of determining whether or not the edge ring FR needs to be replaced based on the RF integration time, the controller CU determines that it is necessary to replace the edge ring FR when the RF integration time has reached a threshold value. On the other hand, the controller CU determines that it is not necessary to replace the edge ring FR when the RF integration time has not reached the threshold value. The threshold value is determined by a preliminary test or the like depending on types of materials of the edge ring FR, or the like.

In the case of determining whether or not the edge ring FR needs to be replaced based on the RF integration power, the controller CU determines that it is necessary to replace the edge ring FR when the RF integration power has reached the threshold value. On the other hand, the controller CU determines that it is not necessary to replace the edge ring FR when the RF integration power has not reached the threshold value. The threshold value is determined by a preliminary test or the like depending on types of materials of the edge ring FR, or the like.

In the case of determining whether or not the edge ring FR needs to be replaced based on the integration value of the specific step of the recipe, the controller CU determines that it is necessary to replace the edge ring FR when the RF integration time or the RF integration power has reached the threshold value in the specific step. On the other hand, the controller CU determines that it is not necessary to replace the edge ring FR when the RF integration time or the RF integration power has not reached the threshold value in the specific step. In the case of determining whether or not the edge ring FR needs to be replaced based on the integration value of the specific step of the recipe, the replacement timing of the edge ring FR can be calculated based on the step in which the RF power is applied and the edge ring FR is consumed. Therefore, it is possible to calculate the replacement timing of the edge ring FR with particularly high accuracy. The threshold value is determined by a preliminary test or the like depending on types of materials of the edge ring FR, or the like.

When it is determined in the consumption degree determination step S10 that the edge ring FR placed on the stage of the process module PM12 needs to be replaced, the controller CU performs the replaceability determination step S20. When it is determined in the consumption degree determination step S10 that it is unnecessary to replace the edge ring FR placed on the stage of the process module PM12, the controller CU repeats the consumption degree determination step S10.

In the replaceability determination step S20, it is determined whether or not the state of the processing system PS allows replacement of the edge ring FR. In the replaceability determination step S20, the controller CU determines whether or not the state of the processing system PS allows replacement of the edge ring FR. Specifically, the controller CU determines that the edge ring FR can be replaced, for example, when the processing of the substrate W is not being performed in the process module PM12 where the edge ring FR will be replaced. On the other hand, the controller CU determines that the edge ring FR cannot be replaced when the processing of the substrate W is being performed in the process module PM12. Further, the controller CU may determine that the edge ring FR can be replaced, for example, when the processing of the substrate W of the same lot as that of the substrate W that is being processed in the process module PM12 where the edge ring FR will be replaced is completed. In that case, the controller CU determines that the edge ring FR cannot be replaced until the processing of the substrate W of the same lot as that of the substrate W that is being processed in the process module PM12 is completed.

When it is determined in the replaceability determination step S20 that the edge ring FR can be replaced in the processing system PS, the controller CU performs the first cleaning step S30. When it is determined in the replaceability determination step S20 that the edge ring FR cannot be replaced in the processing system PS, the controller CU repeats the replaceability determination step S20.

In the first cleaning step S30, a cleaning process of the process module PM12 is executed. In the first cleaning step S30, the controller CU executes the cleaning process of the process module PM12 by controlling a gas introduction system, an exhaust system, a power introduction system, or the like. In the cleaning process, deposits in the process module PM12 generated by plasma processing are removed by plasma of a processing gas or the like, and the inside of the process module PM12 becomes stable in a clean state. By executing the first cleaning step S30, it is possible to prevent the deposits in the process module PM12 from being rolled up when the edge ring FR is unloaded from the stage in the unloading step S40. The processing gas may be oxygen (O₂) gas, fluorocarbon (CF) gas, nitrogen (N₂) gas, argon (Ar) gas, helium (He) gas, or a mixed gas of two or more thereof. Further, in the case of executing the cleaning process the process module PM12, the cleaning process may be executed in a state where the substrate W such as a dummy wafer or the like is placed on the upper surface of the electrostatic chuck 112 depending on processing conditions in order to protect the electrostatic chuck 112 of the stage. When the deposits are not likely to be rolled up, such as when there is no deposit in the process module PM12 or the like, the first cleaning step S30 may not be executed. When the edge ring FR is attracted on the stage by the electrostatic chuck 112, an antistatic process is performed until a next unloading step S40 is started.

In the unloading step S40, the edge ring FR is unloaded from the process module PM12 without opening the process module PM12 to the atmosphere. In the unloading step S40, the controller CU controls the individual components of the processing system PS to unload the edge ring FR from the process module PM12 without opening the process module PM12 to the atmosphere. Specifically, the gate valve G1 is opened, and the edge ring FR placed on the stage in the process module PM12 is unloaded from the process module PM12 by the transfer robot TR2. Then, the gate valve G4 is opened, and the edge ring FR unloaded from the process module PM12 is stored in the storage module SM by the transfer robot TR2.

In the second cleaning step S50, the surface of the stage of the process module PM12 on which the edge ring FR is placed is cleaned. In the second cleaning step S50, the controller CU performs the cleaning process on the surface of the stage of the process module PM12 on which the edge ring FR is placed by controlling the gas introduction system, the exhaust system, the power introduction system, or the like. The cleaning process in the second cleaning step S50 can be performed, for example, in the same manner as that in the first cleaning step S30. In other words, the processing gas may be, e.g., O₂ gas, CF-based gas, N₂ gas, Ar gas, He gas, or a mixed gas of two or more thereof. Further, in the case of performing the cleaning process of the process module PM 12, the cleaning process may be performed in a state where the substrate W such as a dummy wafer is placed on the upper surface of the electrostatic chuck 112 depending on processing conditions in order to protect the electrostatic chuck 112 of the stage. The second cleaning step S50 may be omitted.

In the loading step S60, the edge ring FR is loaded into the process module PM12 and placed on the stage without opening the process module PM12 to the atmosphere. In the loading step S60, the controller CU controls the individual components of the processing system PS to load the edge ring FR into the process module PM12 without opening the process module PM12 to the atmosphere. Specifically, the gate valve G4 is opened, and an unused edge ring FR in the storage module SM is unloaded by the transfer robot TR2. Then, the gate valve G1 is opened, and the unused edge ring FR is loaded into the process module PM12 and placed on the stage by the transfer robot TR2. For example, the controller CU controls the individual components of the processing system PS to place the edge ring FR stored in the storage module SM on the stage in the process module PM12 by the transfer method shown in FIGS. 20A to 20D and 21A to 21D.

In the seasoning step S70, a seasoning process of the process module PM12 is performed. In the seasoning step S70, the controller CU performs the seasoning process of the process module PM12 by controlling the gas introduction system, the exhaust system, the power introduction system, or the like. The seasoning process is for stabilizing a temperature in the process module PM12 or a state of deposits by performing predetermined plasma processing. Further, in the seasoning step S70, a quality control wafer may be loaded into the process module PM12 after the seasoning process of the process module PM12, and then may be subjected to predetermine processing. Accordingly, it is possible to check whether or not the state of the process module PM12 is normal. The seasoning step S70 may be omitted.

As described above, in accordance with the processing system PS of the embodiment, the edge ring FR is unloaded from the process module PM12 by the transfer robot TR2 without opening the process module PM12 to the atmosphere. Next, the inside of the process module PM12 is cleaned and, then, the edge ring FR is loaded into the process module PM12 by the transfer robot TR2. Accordingly, it is possible to replace only the edge ring FR without an operator's manual replacement of the edge ring FR. Hence, a time required to replace the edge ring FR can be shortened, and the productivity is improved. Further, by cleaning the surface on which the edge ring FR is placed before the loading of the edge ring FR, it is possible to suppress deposition of deposits between the edge ring FR and the surface on which the edge ring FR is placed. As a result, the contact therebetween is improved, and good temperature controllability of the edge ring FR can be maintained.

The same method as that used for replacing only the edge ring FR can also be applied to the case of replacing the edge ring FR and the cover ring CR placed on the stage (the electrostatic chuck 112) of the process module PM12 at the same time. In that case, in the consumption degree determination step S10, the controller CU determines whether or not the edge ring FR and the cover ring CR placed on the stage of the process module PM12 need to be replaced. In the unloading step S40, the controller CU controls the individual components of the processing system PS to unload the edge ring FR and the cover ring CR placed on the stage in the process module PM12. In the loading step S60, the controller CU controls the individual components of the processing system PS to place the edge ring FR and the cover ring CR stored in the storage module SM on the stage in the process module PM12 by the transfer method shown in FIGS. 18A to 18D.

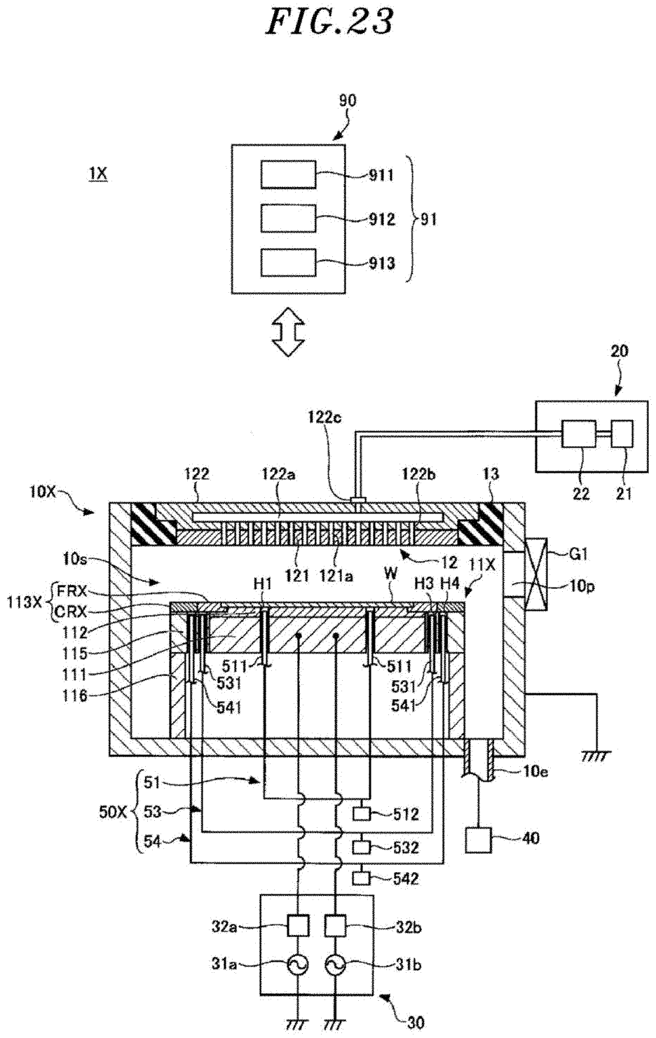

Another example of the plasma processing apparatus used as the process modules PM1 to PM12 of the processing system PS of FIG. 1 will be described with reference to FIGS. 23 to 25.

A plasma processing apparatus 1X includes a plasma processing chamber 10X and an elevating mechanism 50X, instead of the plasma processing chamber 10 and the elevating mechanism 50 in the plasma processing apparatus 1. The other configurations may be the same as those of the plasma processing apparatus 1.

The plasma processing chamber 10X includes a substrate support 11X and an upper electrode 12. The substrate support 11X is disposed in a lower region of a plasma processing space 10s in the plasma processing chamber 10X. The upper electrode 12 is disposed above the substrate support 11X and may function as a part of a ceiling plate of the plasma processing chamber 10X.

The substrate support 11X supports the substrate W in the plasma processing space 10s. The substrate support 11X includes a lower electrode 111, an electrostatic chuck 112, a ring assembly 113X, an insulator 115, and a base 116. The electrostatic chuck 112 is disposed on the lower electrode 111. The electrostatic chuck 112 supports the substrate W on an upper surface thereof. The ring assembly 113X includes an edge ring FRX and a cover ring CRX. The edge ring FRX has a ring shape and is disposed around the substrate W on an upper surface of a peripheral portion of the lower electrode 111. The edge ring FRX improves, for example, uniformity of plasma processing. The cover ring CRX has a ring shape and is disposed at an outer peripheral portion of the edge ring FRX. The cover ring CRX protects, for example, the upper surface of the insulator 115 from plasma. In the example of FIG. 23, an outer diameter of the edge ring FRX is smaller than or equal to an inner diameter of the cover ring CRX. That is, in plan view, the edge ring FRX and the cover ring CRX do not overlap. Accordingly, the edge ring FRX and the cover ring CRX are raised and lowered independently. The insulator 115 is disposed on the base 116 to surround the lower electrode 111. The base 116 is fixed to a bottom portion of the plasma processing chamber 10X and supports the lower electrode 111 and the insulator 115.

The elevating mechanism 50X raises and lowers the substrate W, the edge ring FRX, and the cover ring CRX. The elevating mechanism 50X includes a first elevating mechanism 51, a third elevating mechanism 53, and a fourth elevating mechanism 54.

The first elevating mechanism 51 includes a plurality of support pins 511 and an actuator 512. The plurality of support pins 511 are inserted into the through-holes H1 formed in the lower electrode 111 and the electrostatic chuck 112 to protrude and retract with respect to the upper surface of the electrostatic chuck 112. When the plurality of support pins 511 protrude from the upper surface of the electrostatic chuck 112, upper ends of the plurality of support pins 511 are in contact with the bottom surface of the substrate W to support the substrate W. The actuator 512 raises and lowers the plurality of support pins 511. The actuator 512 may be a motor such as a DC motor, a stepping motor, or a linear motor, an air driving mechanism, a piezo actuator, or the like. The first elevating mechanism 51 raises and lowers the plurality of support pins 511 to transfer the substrate W between the transfer robots TR1 and TR2 and the support 11, for example.

The third elevating mechanism 53 includes a plurality of support pins 531 and an actuator 532. The plurality of support pins 531 are inserted into through-holes H3 formed in the insulator 115 to protrude and retract with respect to the upper surface of the insulator 115. When the plurality of support pins 531 protrude from the upper surface of the insulator 115, upper ends of the plurality of support pins 531 are in contact with a bottom surface of the edge ring FRX to support the edge ring FRX. The actuator 532 raises and lowers the plurality of support pins 531. The actuator 532 may be, e.g., the same as the actuator 512.

The fourth elevating mechanism 54 includes a plurality of support pins 541 and an actuator 542. The plurality of support pins 541 are inserted into through-holes H4 formed in the insulator 115 to protrude and retract with respect to the upper surface of the insulator 115. When the plurality of support pins 541 protrude from the upper surface of the insulator 115, upper ends of the plurality of support pins 541 are in contact with a bottom surface of the cover ring CRX to support the cover ring CRX. The actuator 542 raises and lowers the plurality of support pins 541. The actuator 542 may be, e.g., the same as the actuator 512.

In the elevating mechanism 50X, the plurality of support pins 531 and 541 are raised and lowered when the edge ring FRX and the cover ring CRX are transferred between the transfer robots TR1 and TR2 and the substrate support 11. For example, in the case of unloading the edge ring FRX and the cover ring CRX placed on the electrostatic chuck 112 by the transfer robots TR1 and TR2, the plurality of support pins 531 and 541 are raised as shown in FIG. 24. Accordingly, the edge ring FRX is lifted by the plurality of support pins 531 and the cover ring CRX is lifted by the plurality of support pins 541, thereby simultaneously unloading the edge ring FRX and the cover ring CRX by the transfer robots TR1 and TR2.

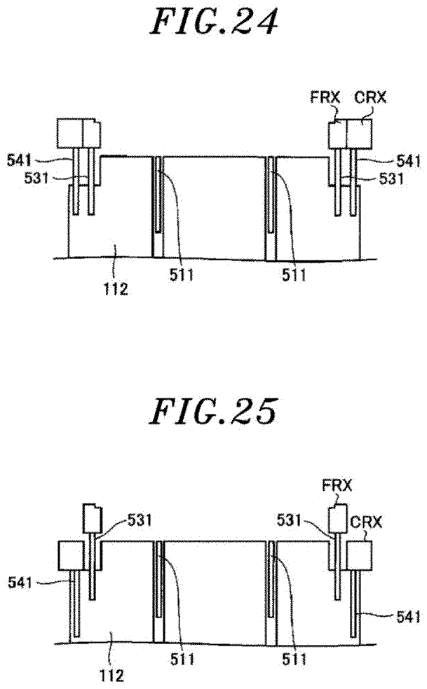

Further, in the elevating mechanism 50X, the support pins 531 are raised and lowered when only the edge ring FRX is transferred between the transfer robots TR1 and TR2 and the substrate support 11. For example, in the case of unloading only the edge ring FRX placed on the electrostatic chuck 112 by the transfer robots TR1 and TR2, the plurality of support pins 531 are raised as shown in FIG. 25. Accordingly, only the edge ring FRX can be lifted by the plurality of support pins 531 and unloaded by the transfer robot TR1.

In the above embodiment, the edge ring FR and FRX and the cover ring CR and CRX are examples of an annular member; the edge rings FR and FRX are examples of an inner ring; and the cover ring CR and CRX are examples of an outer ring. Further, the transfer robots TR1 and TR2 are examples of a transfer device. Further, the support pin 521 is an example of a first support pin; the support pin 511 is an example of a second support pin; the support pin 531 is an example of a third support pin; and the support pin 541 is an example of a fourth support pin.

The above-described embodiments are illustrative but not restrictive in all respects. The above-described embodiments may be omitted, replaced, or changed in various forms without departing from the scope of the appended claims and the gist thereof.

In the above embodiment, the elevating mechanisms 50 and 50X have been described as the mechanism for raising and lowering the edge ring FR and/or the cover ring CR. However, the present disclosure is not limited thereto. For example, when the outer peripheral portion of the edge ring FR and the inner peripheral portion of the cover ring CR overlap, the edge ring FR and the cover ring CR can be independently raised and lowered by support pins, each having a first holder that fits into a through-hole formed in the cover ring CR and a second holder connected to the first holder in an axial direction and having a protrusion protruding from an outer circumference of the first holder. For example, only the edge ring FR can be lifted by allowing the first holder to penetrate through the through-hole of the cover ring CR and bringing a tip end of the first holder into contact with the back surface of the cover ring CR. Further, for example, only the cover ring CR can be lifted by allowing the first holder to penetrate through the through-hole of the cover ring CR and bringing the protrusion of the second holder into contact with the back surface of the cover ring CR. Details of this configuration is disclosed in U.S. Patent Application Publication No. 2020/0219753.

In the above embodiment, the case of transferring the edge ring between the storage module and the process module has been described. However, the present disclosure is not limited thereto, and may also be applied to a case of transferring another consumable part disposed in the process module, such as the cover ring, the ceiling plate of the upper electrode, or the like, instead of the edge ring.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A storage container for accommodating an annular member having a notch on at least one of an outer circumference and an inner circumference thereof, comprising:
a base plate on which the annular member is placed,
wherein the base plate comprises a plurality of guide pins that protrude from the base plate and are configured to position the annular member, and
wherein the plurality of guide pins include a pin engaged with the notch.

2. The storage container of claim 1, wherein the base plate is arranged in multiple stages.

3. The storage container of claim 1, wherein the base plate comprises:
a placement surface on which the annular member is placed; and
a fork insertion groove recessed with respect to the placement surface and into which a fork of a transfer robot configured to transfer the annular member is inserted.

4. The storage container of claim 2, wherein the base plate comprises:
a placement surface on which the annular member is placed; and
a fork insertion groove recessed with respect to the placement surface and into which a fork of a transfer robot configured to transfer the annular member is inserted.

5. The storage container of claim 1, wherein the plurality of guide pins have a conical shape tapering toward a tip end.

6. The storage container of claim 2, wherein the plurality of guide pins have a conical shape tapering toward a tip end.

7. The storage container of claim 1, the plurality of guide pins are brought into contact with the outer circumference of the annular member to position the annular member.

8. The storage container of claim 2, the plurality of guide pins are brought into contact with the outer circumference of the annular member to position the annular member.

9. The storage container of claim 1, wherein the guide pins are brought into contact with the inner circumference of the annular member to position the annular member.

10. The storage container of claim 2, wherein the guide pins are brought into contact with the inner circumference of the annular member to position the annular member.

11. The storage container of claim 1, wherein the annular member is disposed around a substrate during plasma processing.

12. The storage container of claim 2, wherein the annular member is disposed around a substrate during plasma processing.

13. The storage container of claim 1, wherein the annular member comprises a plurality of notches spaced apart from each other in a circumferential direction, and
the plurality of guide pins include a plurality of pins that are respectively engaged with the plurality of notches.

14. The storage container of claim 2, wherein the annular member includes a plurality of notches spaced apart from each other in a circumferential direction, and
the plurality of guide pins include a plurality of pins that are respectively engaged with the plurality of notches.

15. The storage container of claim 1, wherein the notch has a V shape in a plan view.

16. The storage container of claim 2, wherein the notch has a V shape in a plan view.

17. A processing system comprising:
a storage module including a storage container accommodating an annular member having a notch on at least one of an outer circumference and an inner circumference thereof; and
a vacuum transfer module that is connected to the storage module and includes a transfer robot configured to transfer the annular member to the storage container,
wherein the storage container includes:
a base plate on which the annular member is placed; and
a plurality of guide pins that protrude from the base plate and are configured to position the annular member,
wherein the plurality of guide pins include a pin engaged with the notch.
